(19) United States
(12) Patent Application Publication
(10) Pub. No.: US 2022/0052229 A1
(43) Pub. Date: Feb. 17, 2022

(54) LIGHT-EMITTING DEVICE PACKAGE CAPABLE OF IMPLEMENTING SURFACE LIGHT SOURCE, LIGHT-EMITTING MODULE, AND MANUFACTURING METHOD THEREFOR

(71) Applicant: LUMENS CO., LTD., Yongin-si, Gyeonggi-do (KR)

(72) Inventors: Chun Ki MIN, Yongin-si (KR); Yong Shik YANG, Yongin-si (KR); Dong Won SUK, Yongin-si (KR); Su Jong KIM, Yongin-si (KR); Hyun Young DU, Yongin-si (KR)

(73) Assignee: LUMENS CO., LTD., Yongin-si, Gyeonggi-do (KR)

(21) Appl. No.: 17/276,582

(22) PCT Filed: Aug. 26, 2019
(86) PCT No.: PCT/KR2019/010855

§ 371 Date: Mar. 16, 2021

(30) Foreign Application Priority Data
Sep. 17, 2018 (KR) 10-2018-0110944
Nov. 12, 2018 (KR) 10-2018-0138163

(51) Int. Cl. H01L 33/48; H01L 33/54; H01L 33/46; H01L 33/00; H01L 25/075

(52) U.S. Cl. CPC H01L 33/486; H01L 33/54; H01L 33/46; H01L 2933/005; H01L 25/075; H01L 2933/0025; H01L 33/005

(57) ABSTRACT

A surface light source slim module mounted to a vehicle includes: a substrate; a plurality of packages; a first reflective layer formed on top of the substrate and having a plurality of holes; a molding member, which is formed on top of the first reflective layer, covers the plurality of packages and the first reflective layer, and includes a front portion through which light is output and a rear portion facing the front portion; and a second reflective layer formed on top of the molding member.

### TECHNICAL FIELD

The present disclosure relates to a light-emitting device package, a light-emitting module, and a manufacturing method thereof and, more particularly, to a light-emitting device package capable of implementing a surface light source by using a light-emitting device, which is a point light source, a light-emitting module, and a manufacturing method therefor.

### BACKGROUND ART

A light-emitting device (LED) is a semiconductor device that converts electric energy into light energy. A light-emitting device has advantages like low power consumption, semi-permanent life, fast response speed, safety, and environmental friendliness as compared with a conventional light source like a fluorescent lamp and an incandescent lamp.

Therefore, many researches are being conducted to replace existing light sources with light-emitting devices, and light-emitting devices are being increasingly used as light sources of various lamps used indoors and outdoors, liquid crystal display devices, electronic displays, and lighting devices like street lamps. Such light-emitting devices are manufactured into various types of light-emitting device packages by mounting chips on a lead frame and molding the chips in a desired form.

A light-emitting device package is widely used as a lighting device for a vehicle due to the above-stated advantages. Recently, along with the development of lighting technology, light-emitting device packages used for external lighting of a vehicle are gradually changing from point light sources to surface light sources or line light sources. Since a surface light source or a line light source has high uniformity of light output as compared to a point light source, the surface light source or the line light source is less dazzling and forms a smooth shadow, thereby exhibiting high aesthetic impression. Therefore, preference thereof is increasing.

In particular, in the case of an auxiliary brake lamp like a center high mount stop lamp (CHMSL) positioned on a rear glass of a vehicle, a surface from which light is output has a shape having a horizontal length direction longer than a height due to a characteristic of a position on which the auxiliary brake lamp is mounted. When a conventional light-emitting module using a point light source is used in such an auxiliary brake lamp, color uniformity is deteriorated due to color deviation between a position where the light-emitting device is installed and a position where the light-emitting device is not installed.

Meanwhile, side-view type light-emitting device packages are frequently used in small electronic communication devices like a mobile phone and a personal digital assistant (PDA), whereas a top-view type light-emitting device packages are frequently used in medium and large electronic communication devices like a TV and a monitor. The side-view type light-emitting device package has a side-view type light-emitting structure in which light is provided from a side surface of a light guide plate and has an advantage that a thickness of a light-emitting device may be reduced as compared to a top-view type light-emitting device package.

However, a side-view type light-emitting device package according to the related art is unable to rapidly and effectively dissipate a large amount of heat generated from light-emitting devices due to structural characteristics of a substrate or a lead frame disposed in a vertical direction, and thus it is difficult to manufacture a high power light-emitting device package. Also, as technology of an electronic communication device like a mobile phone or a PDA has recently been developed, the thickness of a communication device is gradually being reduced, and thus reduction of a thickness of a display device mounted in a corresponding device is being demanded. Therefore, it is necessary to develop a side-view type light-emitting device package having a minimized thickness and improved heat dissipation characteristics.

### DESCRIPTION OF EMBODIMENTS

### Technical Problem

The purpose of the present disclosure is to solve the above-mentioned problems and other problems. The present disclosure also provides a surface light source slim module capable of reducing color deviation of emitted light and improving color uniformity and a manufacturing method therefor.

The present disclosure also provides a surface light source slim module for implementing external lighting devices of a vehicle with surface light sources to improve light intensity output and aesthetic impression when viewed from the outside and a manufacturing method therefor.

The present disclosure also provides a side-view type light-emitting device package having a reduced thickness and improved heat dissipation characteristics and a manufacturing method therefor.

The present disclosure also provides a side-view type light-emitting device package having low thermal resistance and improved light extraction efficiency and a manufacturing method therefor.

The present disclosure also provides a side-view type light-emitting device package that emits light in a first direction through a first side surface, light in a second direction through a second side surface, and light in a third direction through a third side surface, and a manufacturing method therefor.

### Solution to Problem

According to an aspect of the present disclosure, there is provided a surface light source slim module including: a substrate extending from one side to another; a plurality of packages mounted on top of the substrate in a direction from one side to another; a first reflective layer formed on top of the substrate and including a plurality of holes; a molding member, which is formed on top of the first reflective layer, covers the plurality of packages and the first reflective layer, and includes a front portion through which light is output and a rear portion facing the front portion; and a second reflective layer formed on top of the molding member, wherein the first reflective layer and the second reflective layer reflect light output from the plurality of packages to be concentrated on the front portion of the molding member, and a direction in which light is output from the plurality of packages and a direction in which light is output to the front portion of the molding member are parallel to each other.

According to another aspect of the present disclosure, there is provided a surface light source slim module including: a substrate extending from one side to another; a plurality of packages mounted on top of the substrate in a direction from one side to another; a first reflective layer formed on top of the substrate and including a plurality of holes; a molding member, which is formed on top of the first reflective layer, covers the plurality of packages and the first reflective layer, and includes a front portion through which light is output and a rear portion facing the front portion; a second reflective layer formed on top of the molding member; and a third reflective layer stacked on top of the first reflective layer to reflect light output to the rear portion of the molding member toward the front portion of the molding member, wherein the first reflective layer and the second reflective layer reflect light output from the plurality of packages to be concentrated on the front portion of the molding member, and a direction in which light is output from the plurality of packages and a direction in which light is output to the front portion of the molding member are perpendicular to each other.

According to another aspect of the present disclosure, there is provided a method of manufacturing a surface light source slim module, the method including: preparing a substrate extending from one side to another; mounting a plurality of light-emitting device packages on top of the substrate to be apart from one another in a direction from one side to another; forming a first reflective layer on top of the substrate on which the plurality of light-emitting device packages are mounted; forming a molding member, which includes a front portion through which light is output and a rear portion facing the front portion, on top of the first reflective layer; and forming a second reflective layer on top of the molding member, wherein, in the mounting of the light-emitting device packages, a direction in which light is output from the plurality of light-emitting device packages is identical and parallel to a direction in which light is output to the front portion of the molding member.

According to another aspect of the present disclosure, there is provided a side-view type light-emitting device package including: light-emitting devices; a molding member, which is configured to transmit light emitted from the light-emitting devices, includes an inclined surface and a first side surface, a second side surface, and a third side surface connected to the inclined surface, and is disposed to surround the light-emitting devices; and a reflective member, which includes a reflective surface formed in correspondence to a shape of the inclined surface of the molding member, is positioned for the reflective surface to face the inclined surface of the molding member, and reflects light emitted by the light-emitting devices, wherein a diagonal boundary surface is formed between the molding member and the reflective member.

According to another aspect of the present disclosure, there is provided a side-view type light-emitting device package including: light-emitting devices; a molding member, which is configured to transmit light emitted from the light-emitting devices, includes an inclined surface and a first side surface, a second side surface, and a third side surface connected to the inclined surface, and is disposed to surround the light-emitting devices; and a reflective member, which includes a reflective surface formed in correspondence to a shape of the inclined surface of the molding member, is positioned for the reflective surface to face the inclined surface of the molding member, and reflects light emitted by the light-emitting devices, wherein the light-emitting devices are inserted into the molding member, and the first side surface, the second side surface, and the third side surface of the molding member are exposed to the outside.

### Advantageous Effects of Disclosure

The present disclosure is proposed to solve the above-stated problems and may reduce color deviation of emitted light and improve color uniformity.

Also, the present disclosure may implement an external lighting of a vehicle with a surface light source, thereby increasing output light intensity and improving the aesthetic impression when the vehicle is viewed from the outside.

Also, the present disclosure may effectively emit light emitted from light-emitting devices through three side surfaces of a package body by including a molding member, which has a preset shape and is formed on a substrate and the light-emitting devices, and a reflective member having a shape corresponding to the shape of the molding member.

Also, the present disclosure may arrange light-emitting devices emitting light in an upward direction on a substrate disposed in a direction parallel to the ground and sequentially arranging a molding member and a reflective member thereon, thereby improving heat dissipation characteristics with a reduced thickness of a package body and improving light extraction efficiency while having a low thermal resistance.

However, the effects according to various embodiments of the present disclosure are not limited to the above-mentioned effects, and other non-mentioned effects may be clearly understood by one of ordinary skills in the art from the descriptions below.

### BRIEF DESCRIPTION OF DRAWINGS

FIG. 1 is a cross-sectional view of a surface light source slim module according to an embodiment of the present disclosure;

FIG. 2 is a diagram for describing a surface light source slim module according to an example embodiment of the present disclosure;

FIG. 3 is a cross-sectional view of a surface light source slim module according to another embodiment of the present disclosure;

FIG. 4 is a cross-sectional view of a surface light source slim module according to another embodiment of the present disclosure;

FIG. 5 is a cross-sectional view of a surface light source slim module according to another embodiment of the present disclosure;

FIG. 6 is a flowchart of a method of manufacturing a surface light source slim module according to another embodiment of the present disclosure;

FIGS. 7 to 10 are diagrams for describing the method of manufacturing a surface light source slim module according to an example embodiment of FIG. 6 in more detail;

FIG. 11 is a plan view of a side-view type light-emitting device package according to an embodiment of the present disclosure;

FIG. 12 is a cross-sectional view of the side-view type light-emitting device package, taken along a line I-I of FIG. 11;

FIG. 13 is a perspective view of a side-view type light-emitting device package according to an embodiment of the present disclosure;

FIG. 14 is a cross-sectional view of a light-emitting device according to an embodiment of the present disclosure;

FIGS. 15A through 15H are diagrams for describing a method of manufacturing a side-view type light-emitting device package according to an embodiment of the present disclosure.

### MODE OF DISCLOSURE

Hereinafter, example embodiments disclosed herein will be described in detail with reference to the accompanying drawings, wherein the same or similar components will be denoted by the same reference numerals regardless of drawing numbers, and repeated descriptions thereof will be omitted. Hereinafter, in the description of embodiments according to the present disclosure, it will be understood that when each layer (or film), a region, a pad, a pattern, or a structure is referred to as being formed “on” or “under” a substrate, each layer (or film), a region, a pad, a pattern, or a structure, the terms “on” and “under” may indicate that the layer (or film), the region, the pad, the pattern, or the structure is “directly” formed on or “indirectly” formed via another layer. Also, a reference for being on/under of each layer will be described based on the drawings. In the drawings, a thickness or a size of each layer is exaggerated, omitted, or schematically illustrated for convenience and clarity of explanation. Also, the size of each component does not entirely reflect an actual size thereof.

In the description of the present disclosure, certain detailed explanations of the related art are omitted when it is deemed that they may unnecessarily obscure the essence of the present disclosure. Also, the accompanying drawings are merely intended to facilitate understanding of the embodiments disclosed herein, and it should be understood that the technical spirits disclosed herein is not limited by the accompanying drawings and includes all changes, equivalents, or substitutes included in the spirit and technical scope of the present disclosure.

The present disclosure provides a surface light source slim module capable of reducing color deviation of emitted light and improving color uniformity and a manufacturing method therefor. The present disclosure also provides a surface light source slim module for implementing external lighting devices of a vehicle with surface light sources to improve light intensity output and aesthetic impression when viewed from the outside and a manufacturing method therefor. The present disclosure also provides a side-view type light-emitting device package having a reduced thickness and improved heat dissipation characteristics and a manufacturing method therefor. The present disclosure also provides a side-view type light-emitting device package having low thermal resistance and improved light extraction efficiency and a manufacturing method therefor. The present disclosure also provides a side-view type light-emitting device package that emits light in a first direction through a first side surface, light in a second direction through a second side surface, and light in a third direction through a third side surface, and a manufacturing method therefor.

Hereinafter, various embodiments of the present disclosure will be described in detail with reference to the drawings.

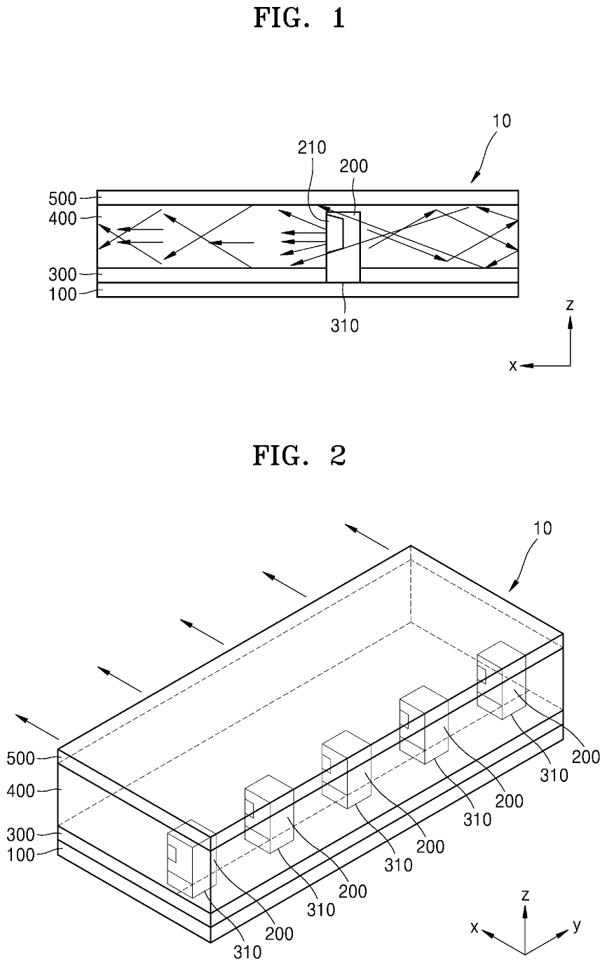

FIG. 1 is a cross-sectional view of a surface light source slim module according to an embodiment of the present disclosure.

Referring to FIG. 1, the surface light source slim module 10 may include a substrate 100, a plurality of packages 200, a first reflective layer 300, a molding member 400, and a second reflective layer 500. In embodiments of FIGS. 1 to 3, the plurality of packages may be side-view packages.

The surface light source slim module 10 may be a light-emitting module for outputting light output from a side-view package 200 mounted therein or a top-view package 220 to be described below in an +x direction of FIG. 1. In this case, a configuration including one surface in the +x direction may be defined as a front portion of the surface light source slim module 10, and a configuration including the other surface in a direction opposite to the +x direction (−x direction) may be defined as a rear portion of the surface light source slim module 10. The surface light source slim module 10 may reflect and diffuse light output from a light-emitting device therein through a molding member and a reflective layer, thereby allowing light to be uniformly output to the outside to the front portion.

The substrate 100 may include a material having suitable mechanical strength and insulation properties or a conductive material to be able to support the side-view package 200 or the top-view package 220 to be described below and may extend from one side to another side. In other words, the substrate 100 may extend in a horizontal direction (e.g., +y direction or −y direction in FIG. 2). For example, the substrate 100 may be a printed circuit board (PCB) in which a multi-layer structure including epoxy-based resin sheets are formed. Also, the substrate 100 may be a flexible printed circuit board (FPCB) formed of a flexible material. Furthermore, the substrate 100 may include a synthetic resin substrate including resin, glass epoxy, etc, a ceramic substrate in consideration of thermal conductivity, a metal substrate including insulated aluminum, copper, zinc, tin, lead, gold, silver, etc., or substrates having a plate shape or a lead frame shape.

In detail, the substrate 100 may be a plate-type metal substrate including a relatively inexpensive metal, e.g., aluminum, iron, or copper, and various insulation layers and the first reflective layer 300 to be described below may be formed on a surface of the substrate 100 by performing various oxidation processes.

Furthermore, the substrate 100 may include at least one selected from among epoxy mold compound (EMC), polyimide (PI), ceramic, graphene, glass synthetic fiber, and combinations thereof in order to improve processability.

The side-view package 200 may be mounted on the substrate 100 and may output light toward the front portion of the substrate 100. A plurality of side-view packages 200 may be arranged to be spaced apart from one another in a direction in which the substrate 100 extends.

The side-view package 200 is a device having a package structure in which a light-emitting diode (LED) is embedded like the top-view package 220 to be described below and may be a type of devices commonly referred to as LED packages. There are various types of light-emitting device packages available according to structures and purposes, and, as an example, the side-view package 200 used as a light source for a backlight module of a display device like a small LCD may be shown.

The side-view package 200 may include a package body formed of a resin material and having a lead frame installed thereon, and a light-emitting device chip 210 may be mounted on a front portion of the package body. In other words, the front portion of the package body in the side-view package 200 is a surface on which the light-emitting device chip 210 is mounted, and, in FIG. 1, the side-view package 200 may be mounted, such that the light-emitting device chip 210 faces in the +x direction to output light to the front portion of the surface light source slim module 10.

The side-view package 200 may be mounted on the substrate 100 at a position a certain distance apart from the front portion of the substrate 100. In detail, the side-view package 200 may be a certain distance apart from the front portion of the substrate 100 according to the size or the shape of the substrate 100 and the size of the side-view package 200. Therefore, a part of light output from the light-emitting device chip 210 of the side-view package 200 may be directly output to the front portion of the surface light source slim module 10, and the other part of the light may be reflected by or diffused through the first reflective layer 300, the molding member 400, and the second reflective layer 500 to be described below and output to the front portion of the surface light source slim module 10. Accordingly, light may be output to the front portion of the surface light source slim module 10 to a uniform degree.

The first reflective layer 300 may be stacked on the substrate 100 and surround a portion of the side-view package 200. The molding member 400 may be formed on the first reflective layer 300, and the second reflective layer 500 may be stacked on the molding member 400. In other words, the first reflective layer 300, the molding member 400, and the second reflective layer 500 may be stacked on the substrate 100 in the order stated. The first reflective layer 300 and the second reflective layer 500 may reflect light output from the side-view package 200, such that light is concentrated on the front portion of the substrate 100.

The first reflective layer 300 may reflect light emitted from the side-view package 200 approximately in the −z direction, thereby emitting the light in the +x direction, which is a lateral direction. Also, the second reflective layer 500 may reflect light emitted from the side-view package 200 approximately in the +z direction, thereby emitting the light in the +x direction, which is a lateral direction.

The first reflective layer 300 may cover an upper portion of the substrate 100, and a plurality of holes 310 may be formed to surround portions of the side-view package 200. The first reflective layer 300 may be formed by performing metal coating on the top surface of the substrate 100, or a metal reflection plate formed in advance may be attached to the upper portion of the substrate 100. Also, the first reflective layer 300 may be a film-type plated with a metal layer and may be formed by stacking a plurality of reflective sheets on the substrate 100.

The first reflective layer 300 may include a material having high reflectivity, e.g., polyester (PET), aluminum, silver, etc. However, the present disclosure is not limited thereto, and other metal materials may also be used.

The plurality of holes 310 may be formed in the first reflective layer 300. Here, the depth of the plurality of holes 310 formed in the first reflective layer 300 may be smaller than the thickness of the plurality of side-view packages 200 or the top-view package 220 mounted on the substrate 100.

In more detail, the holes 310 of the first reflective layer 300 may be formed to accommodate packages in the first reflective layer 300 and to prevent movement of the packages during formation of the first reflective layer 300 on the substrate 100 on which the packages are mounted. Thus, the plurality of holes 310 may be formed to correspond to positions of the packages and sizes of the packages.

Like the first reflective layer 300, the second reflective layer 500 may be formed by performing metal coating on the top surface of the molding member 400 or attaching a metal reflective plate formed in advance to the upper portion of the molding member 400. Also, the second reflective layer 500 may be a film-type plated with a metal layer and may be formed by stacking a plurality of reflective sheets on the molding member 400.

The molding member 400 may cover the first reflective layer 300 and the side-view package 200. In other words, the molding member 400 may be formed on top of the first reflective layer 300 to cover the plurality of packages and the first reflective layer 300 and may include a front portion through which light is output and a rear portion facing the front portion. Although FIG. 1 shows that the molding member 400 also fills up a space between the side-view package 200 and the second reflective layer 500 and cover the side-view package 200, the top surface of the side-view package 200 may directly contact the bottom surface of the second reflective layer 500 depending on a height of the side-view package 200 or a thickness of the surface light source slim module 10.

The molding member 400 may include a light-transmitting material through which light output from the side-view package 200 may pass and may be formed by using a method like a transfer molding method. However, various modifications may be made therein. For example, the molding member 400 may be formed by using a method like injection molding. Examples of resins that may be used to form the molding member 400 may include epoxy.

The molding member 400 may be formed by adding a diffusing agent in order to more smoothly diffuse light. An example of a material constituting the molding member 400 may include SiO₂. Also, an example of a material constituting the diffusing agent used in the molding member 400 may include TiO₂. Although SiO₂, which is given as an example of a material constituting the molding member 400, has an effect of diffusing light, the diffusion effect may be increased by further adding the diffusing agent. In this case, the diffusing agent may be mixed in at a ratio of about 0.01% to about 0.03%.

Based on the above description, it may be seen that a direction in which light is output from the side-view package 200 and a direction in which light is output to the front portion of the molding member 400 are parallel to each other between the first reflective layer 300 and the second reflective layer 500.

FIG. 2 is a diagram for describing a surface light source slim module according to an example embodiment of the present disclosure.

Referring to FIG. 2, it may be seen that the components of the surface light source slim module 10 are arranged along the substrate 100 extending in a horizontal direction (+y direction or −y direction). In FIG. 2, the surface light source slim module 10 may output light in the +x direction, which is a direction toward the front portion. The rear portion of the surface light source slim module 10 may include a component for shielding light output or reflected in the −x direction. Also, a reflector to be described below may be positioned at the rear portion of the surface light source slim module 10 to reflect light output or reflected in the −x direction back toward the front portion of the surface light source slim module 10.

As shown in FIG. 2, the plurality of side-view packages 200 may be a certain interval apart from one another in a direction in which the substrate 100 extends. Also, a length or a height of the front portion through which light is output from the surface light source slim module 10 may vary according to designs.

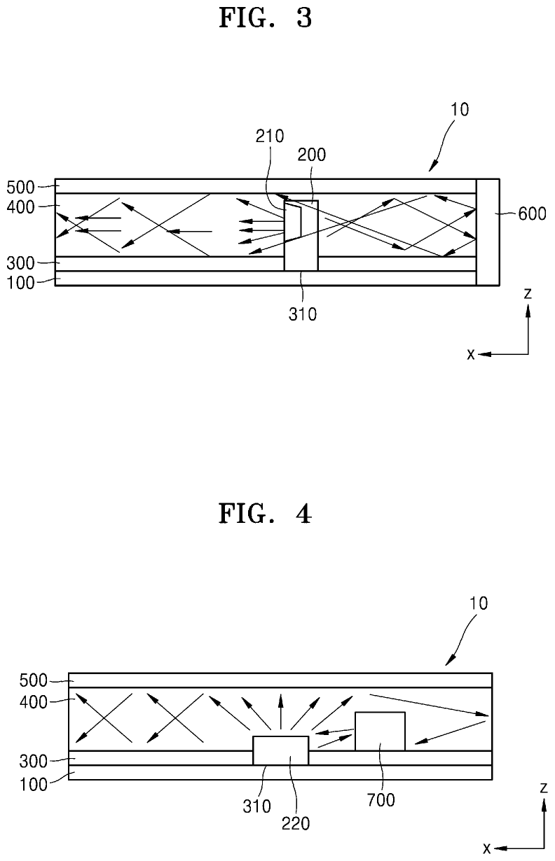

FIG. 3 is a cross-sectional view of a surface light source slim module according to another embodiment of the present disclosure. In the description of FIG. 3, descriptions of components or effects identical to those given above with reference to the drawings will be omitted.

Referring to FIG. 3, it may be seen that a rear reflective member 600 is further included at the rear portion of the surface light source slim module 10. The rear reflective member 600 may be a component for reflecting light output to the rear portion of the molding member 400 toward the front portion of the molding member 400.

In more detail, the rear reflective member 600 may reflect a light beam reflected or diffused in the −x direction from light beams output from the side-view package 200 in the +x direction again. Therefore, light intensity output to the front portion of the surface light source slim module 10 is increased.

The rear reflective member 600 may be located behind the substrate 100 and cover the substrate 100, the first reflective layer 300, the molding member 400, and the second reflective layer 500. The rear reflective member 600 may be formed by performing metal coating on the rear portion 10 of the surface light source slim module or by attaching a metal reflective plate formed in advance to the rear portion of the surface light source slim module 10. Also, the rear reflective member 600 may be a film-type plated with a metal layer and may be formed by stacking a plurality of reflective sheets on the surface light source slim module 10.

The rear reflective member 600 may include a material having high reflectivity, e.g., polyester (PET), aluminum, silver, etc. However, the present disclosure is not limited thereto, and other metal materials may also be used.

FIG. 4 is a cross-sectional view of a surface light source slim module according to another embodiment of the present disclosure. In the description of FIG. 4, descriptions of components or effects identical to those given above with reference to the drawings will be omitted.

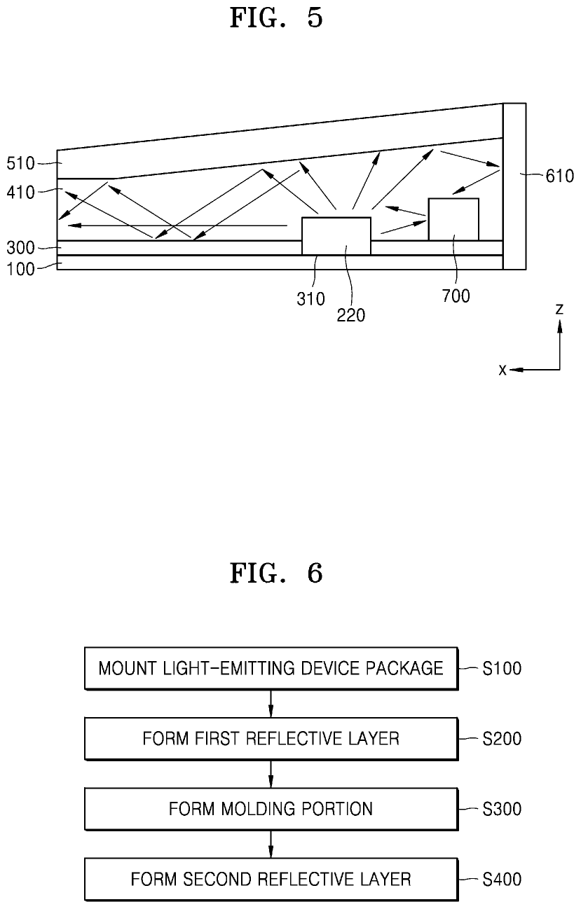

Referring to FIG. 4, it may be seen that the top-view package 220 is mounted on the substrate 100, and a third reflective layer 700 is positioned behind the top-view package 220. In embodiments of FIGS. 4 and 5, the term ‘packages’ may refer to top-view packages.

Like the side-view package 200 described above, the top-view package 220 may be mounted on the substrate 100, and a plurality of top-view packages 220 may be arranged to be apart from one another in a direction in which the substrate 100 extends.

The top-view package 220 is a device having a package structure in which a light-emitting diode (LED) is embedded like side-view package 200 described above and may be another type of devices commonly referred to as LED packages.

The top-view package 220 may include a package body formed of a resin material and having a lead frame installed thereon, and a light-emitting device chip may be mounted on top of the package body. In other words, unlike the side-view package 200, light output from the top-view package 220 may travel in the +z direction from the top-view package 220.

In order to concentrate light output from the top-view package 220 on the front portion of the surface light source slim module 10, the third reflective layer 700 may be further provided in addition to the first reflective layer 300 and the second reflective layer 500. The third reflective layer 700 may be disposed between the top-view package 220 and the rear portion of the surface light source slim module 10.

Based on the above description, in the embodiment of FIG. 4, the first reflective layer 300 and the second reflective layer 500 may reflect light output from the plurality of top-view packages 220 to be concentrated on the front portion of the molding member 400. In this case, a direction in which light is output from the plurality of top-view packages 220 may be perpendicular to a direction in which light is output to the front portion of the molding member 400.

As in the embodiment of FIG. 1, the plurality of holes 310 may be formed in the first reflective layer 300.

In more detail, the holes 310 of the first reflective layer 300 may be formed to accommodate packages in the first reflective layer 300 and to prevent movement of the packages during formation of the first reflective layer 300 on the substrate 100 on which the packages are mounted. Thus, the plurality of holes 310 may be formed to correspond to positions of the packages and sizes of the packages.

The third reflective layer 700 may be formed by performing metal coating on the top surface of the first reflective layer 300, or a metal reflection plate formed in advance may be attached to the upper portion of first reflective layer 300. Also, the third reflective layer 700 may be a film-type plated with a metal layer and may be formed by stacking a plurality of reflective sheets on the first reflective layer 300.

The third reflective layer 700 may include a material having high reflectivity, e.g., polyester (PET), aluminum, silver, etc. However, the present disclosure is not limited thereto, and other metal materials may also be used.

The third reflective layer 700 may be stacked to a height greater than that of the top-view package 220 and may also be stacked to a greater height in order to increase light intensity output to the front portion of the surface light source slim module 10. In other words, the top surface of the third reflective layer 700 may be located higher than the top surface of the top-view package 220.

FIG. 5 is a cross-sectional view of a surface light source slim module according to another embodiment of the present disclosure. Referring to FIG. 5, unlike as in FIG. 4, the thickness of the molding member 410 is changed, and a second reflective layer 510 is formed to be inclined.

Also, it may be seen that a rear reflective member 610 is further provided at the rear portion of the surface light source slim module 10.

Light output from the top-view package 220 may travel not only to the upper portion of the molding member 400, but also to the front portion or the rear portion of the molding member 400. The second reflective layer 510 may be formed to be inclined in order to concentrate light output in different directions on the front portion of the surface light source slim module 10. Light output from the top-view package 220 may be totally reflected through the inclined second reflective layer 510. Also, light reflected to the rear portion of the surface light source slim module 10 may be reflected back toward the front portion of the surface light source slim module 10 through the rear reflective member 610 positioned at the rear portion of the surface light source slim module 10.

In order to form the inclined second reflective layer 510, the molding member 410 may be formed to have a greater thickness at the rear portion of the surface light source slim module 10 than at the front portion of the surface light source slim module 10. The second reflective layer formed in correspondence to the changing thickness of the molding member 410 may be formed to have a greater height at the rear portion of the surface light source slim module 10 than at the front portion of the surface light source slim module 10.

Through the molding member 410 and the second reflective layer 510, brightness and uniformity of light output from the surface light source slim module 10 in which the top-view package 220 is mounted may be increased.

FIG. 6 is a flowchart of a method of manufacturing a surface light source slim module according to another embodiment of the present disclosure.

Referring to FIG. 6, the method of manufacturing a surface light source slim module may include a light-emitting device package mounting operation (operation S100), a first reflective layer forming operation (operation S200), a molding member forming operation (operation S300), and a second reflective layer forming operation (operation S400).

The light-emitting device package mounting operation (operation S100) may be an operation of mounting a plurality of light-emitting device packages on a substrate to be apart from one other in a direction from one side to another. Prior to the light-emitting device package mounting operation (operation S100), an operation of preparing a substrate extending from one side to another may be performed. The light-emitting device package mounting operation (operation S100) may be an operation of mounting light-emitting device packages on top of a substrate by using a surface mounter technology *(SMT). During the process, other device needed for driving a surface light source slim module (e.g., various resistors) may be mounted on the bottom surface of the substrate.

Here, a light-emitting device package may refer to a side-view type or top-view type light-emitting device package. When a light-emitting device package is a side-view type package, in the light-emitting device package mounting operation (operation S100), side-view packages may be mounted, such that light is output to the front portion of the substrate. In detail, the light-emitting device package mounting operation (operation S100) may be an operation of mounting side-view packages, such that light-emitting device chips of the side-view packages face toward the front portion of the substrate.

Here, the light-emitting device package mounting operation (operation S100) may be an operation of mounting the plurality of light-emitting device packages, such that, when the plurality of light-emitting device packages are side-view packages, a direction in which light is output from the side-view packages is identical and parallel to a direction in which light is output toward the front portion of the molding member. On the contrary, the light-emitting device package mounting operation (operation S100) may be an operation of mounting the plurality of light-emitting device packages, such that, when the plurality of light-emitting device packages are top-view packages, a direction in which light is output from the top-view packages is perpendicular to a direction in which light is output toward the front portion of the molding member.

The first reflective layer forming operation (operation S200) may be an operation of forming a first reflective layer on a substrate having mounted thereon a plurality of light-emitting device packages. The first reflective layer may be formed by performing metal coating on the top surface of the substrate or by attaching a metal reflection plate formed in advance to the upper portion of the substrate. Also, the first reflective layer may be a film-type plated with a metal layer and may be formed by stacking a plurality of reflective sheets on the substrate.

When light-emitting device packages mounted in the light-emitting device package mounting operation (operation S100) are top-view packages, an operation of forming a third reflective layer (not shown) may be performed after the first reflective layer forming operation (operation S200).

The operation of forming the third reflective layer may be an operation of forming the third reflective layer on the first reflective layer between the top-view packages and a rear reflective member. The third reflective layer may be formed by performing metal coating on the top surface of the first reflective layer or attaching a metal reflection plate formed in advance to the upper portion of first reflective layer. Also, the third reflective layer may be a film-type plated with a metal layer and may be formed by stacking a plurality of reflective sheets on the first reflective layer.

The molding member forming operation (operation S300) may be an operation of forming a molding member including a front portion from which light is output and a rear portion facing the front portion on top of the first reflective layer. The molding member may be formed on the first reflective layer by using a transfer molding method, injection molding method, etc.

When the light-emitting device packages mounted in the light-emitting device package mounting operation (operation S100) are top-view packages, the molding member forming operation (operation S300) may be an operation of forming the molding member, such that the thickness of the molding member gradually increases in a direction from the front portion of the substrate to the rear portion of the substrate.

The second reflective layer forming operation (operation S400) may be an operation of forming a second reflective layer on top of the molding member. The second reflective layer may be formed by performing metal coating on the top surface of the molding member or by attaching a metal reflection plate formed in advance to the upper portion of the molding member. Also, the second reflective layer may be a film-type plated with a metal layer and may be formed by stacking a plurality of reflective sheets on the molding member.

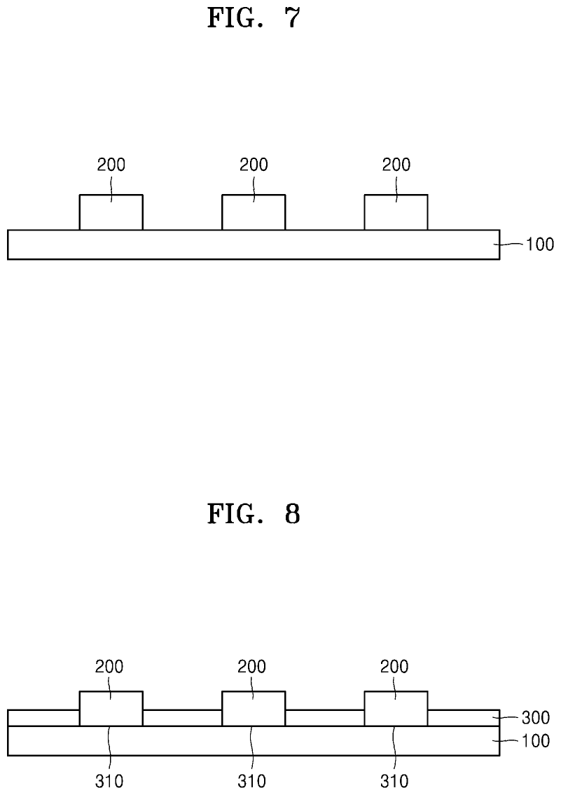

After second reflective layer forming operation (operation S400), an operation of forming a rear reflective member at the rear portion of the surface light source slim module (not shown) may be performed. The rear reflective member may be formed by performing metal coating on the rear portion of the surface light source slim module or by attaching a metal reflective plate formed in advance to the rear portion of the surface light source slim module. Also, the rear reflective member may be a film-type plated with a metal layer and may be formed by stacking a plurality of reflective sheets on the surface light source slim module. FIGS. 7 to 10 are diagrams for describing the method of manufacturing a surface light source slim module according to an example embodiment of FIG. 6 in more detail.

FIGS. 7 to 10 illustrate a process of manufacturing the surface light source slim module as described above when viewed from the front of the surface light source slim module. Although FIGS. 7 to 10 show that the number of the side-view packages 200 mounted on the surface light source slim module is three (3), the present disclosure is not limited thereto, and less or more side-view packages 200 may be mounted.

FIG. 7 is a diagram for describing the light-emitting device package mounting operation (operation S100) of FIG. 6. Referring to FIG. 7, it may be seen that a plurality of side-view packages 200 are mounted on the substrate 100 at regular intervals. As described above, not only the side-view package 200, but also the top-view package may be mounted on the substrate 100.

FIG. 8 is a diagram for describing the first reflective layer forming operation (operation S200) of FIG. 6. Referring to FIG. 8, it may be seen that the first reflective layer 300 is formed on the substrate 100 on which the side-view packages 200 are mounted. In this case, the side-view packages 200 may be mounted in correspondence to positions of the holes 310 formed in the first reflective layer 300 in advance.

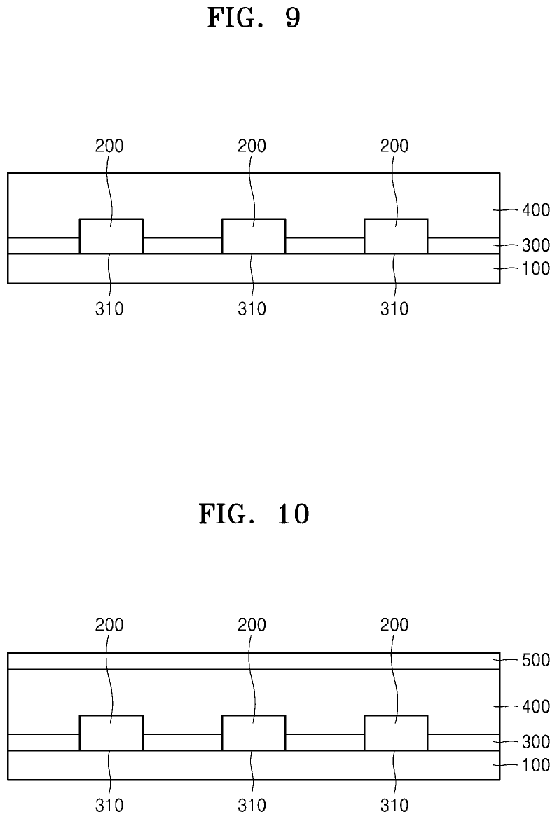

FIG. 9 is a diagram for describing the molding member forming operation (operation S300) of FIG. 6. Referring to FIG. 9, it may be seen that the molding member 400 is formed to cover the upper portion of the first reflective layer 300 and the side-view packages 200.

FIG. 10 is a diagram for describing the second reflective layer forming operation (operation S400) of FIG. 6. Referring to FIG. 10, it may be seen that the second reflective layer 500 is formed on the molding member 400.

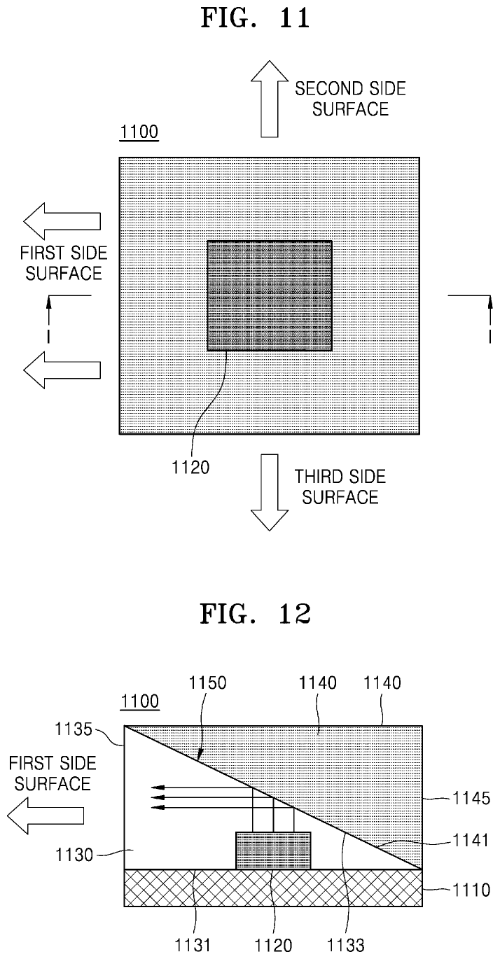

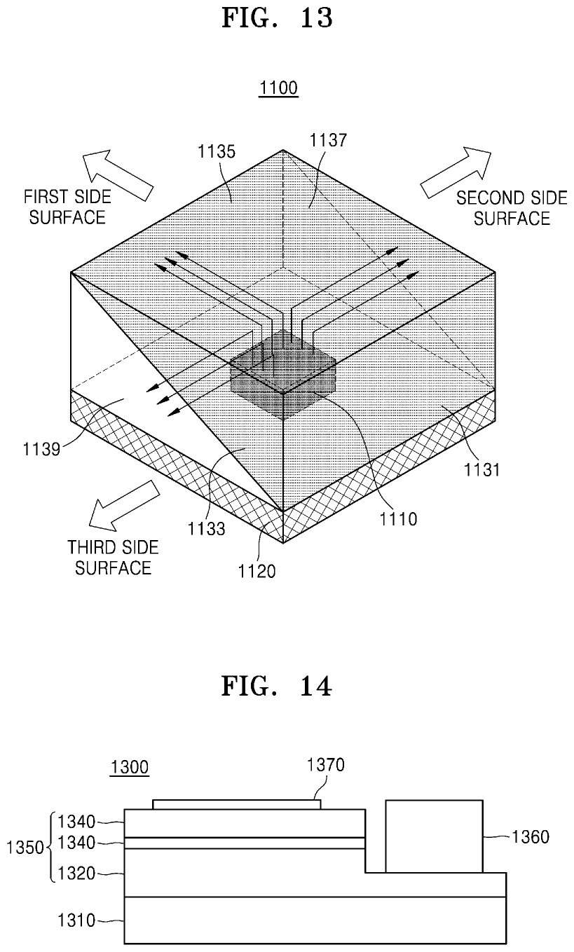

FIG. 11 is a plan view of a side-view type light-emitting device package according to an embodiment of the present disclosure, FIG. 12 is a cross-sectional view of the side-view type light-emitting device package, taken along a line I-I of FIG. 11, and FIG. 13 is a perspective view of a side-view type light-emitting device package according to an embodiment of the present disclosure.

Referring to FIGS. 11 to 13, a side-view type light-emitting device package 1100 according to an embodiment of the present disclosure includes a substrate 1110 disposed in a direction parallel to the ground, a light-emitting device 1120 mounted on the substrate 1110, a molding member 1130 disposed on the light-emitting device 1120, and a reflective member 1140 disposed on the molding member 1130.

The substrate 1110 may be electrically connected to the light-emitting device 1120 and provide a connection for electric signal transmissions between the light-emitting device 1120 and an external device. Here, the substrate 1110 may include a preset circuit pattern. The circuit pattern may include a conductive metal material.

The substrate 1110 may support the light-emitting device 1120 and reflect light emitted from the light-emitting device 1120. Therefore, light emitted from the light-emitting device 1120 may be reflected by the top surface of the substrate 1110 and emitted through side surfaces of the light-emitting device package 1100.

The substrate 1110 may dissipate heat generated from the light-emitting device 1120 to the outside. Since the substrate 1110 is disposed under the light-emitting device 1120 in a horizontal direction (i.e., a direction perpendicular to an optical axis direction of light emitted by the light-emitting device 1120), a heat dissipation path is wider than that of a conventional side-view type light-emitting device package, and thus heat generated from the light-emitting device 1120 may be quickly dissipated in a downward direction.

The substrate 1110 may include a printed circuit board (PCB) or a flexible PCB (FPCB). In another embodiment, a lead frame may be used instead of a substrate. The lead frame may include a first lead for supplying first power to the light-emitting device 1120 and a second lead for supplying second power to the light-emitting device 1120. The first lead and the second lead may function not only as lead electrodes, but also as a heat sink for dissipating heat generated from the light-emitting device 1120 to the outside. The first lead and the second lead may each include a material with excellent thermal conductivity, electric conductivity, and reflectivity, e.g., aluminum (Al), silver (Ag), gold (Au), copper (Cu), or an alloy thereof.

The light-emitting device 1120 may be surface-mounted on the substrate 1110 through the surface mount technology (SMT) and emit light in an upward direction. A structure of the light-emitting device 1120 surface-mounted on the substrate 1110 may be any one of a flip-chip type structure, a vertical type structure, and a lateral type structure. According to the structure of the light-emitting device 1120, the light-emitting device 1120 may be electrically connected to the substrate 1110 through wire bonding or flip-chip bonding.

The light-emitting device 1120 may include a growth substrate, a first conductivity type semiconductor layer under the growth substrate, an active layer under the first conductivity type semiconductor layer, a second conductivity type semiconductor layer under the active layer, a second conductivity type metal layer under the second conductivity type semiconductor layer, and a first conductivity type metal layer under the first conductivity type semiconductor layer.

The light-emitting device 1120 may emit light having different wavelengths according to composition ratios of a compound semiconductor. Although the present embodiment exemplifies that the light-emitting device 1120 emits light having a red wavelength, the present disclosure is not limited thereto.

The molding member (or the filling member) 1130 may be disposed on the substrate 1110 and the light-emitting device 1120 and may be formed to completely surround the top surface and side surfaces of the light-emitting device 1120.

The molding member 1130 may protect the light-emitting device 1120 from an external environment or an external impact and may form a body of the light-emitting device package 1100 (hereinafter referred to as a package body, for convenience of explanation) together with the reflective member 1140. Also, the molding member 1130 may transmit light emitted from the light-emitting device 1120 to the outside.

The molding member 1130 may include an epoxy resin or a silicon resin having excellent light transmittance and thermal conductivity, but the material therefor is not limited thereto. According to another embodiment, the molding member 1130 may further include a light conversion material for converting a wavelength of light emitted from the light-emitting device 1120. Also, the molding member 1130 may further include an adhesive material for improving adhesion between the molding member 1130 and the substrate 1110 and adhesion between the molding member 1130 and the light-emitting device 1120.

The molding member 1130 may be formed on the substrate 1110 and the light-emitting device 1120 by using an appropriate molding method, e.g., an injection molding method or a transfer molding method.

The molding member 1130 may be formed in a triangular prism-like shape to emit light through three side surfaces of the light-emitting device package 1100. A cross-section of the molding member 1130 may have a triangular shape, and more preferably, a right-angled triangular shape.

The molding member 1130 includes a bottom surface 1131 that meets the substrate 1110, a top surface (i.e., an inclined surface) 1133 that meets the reflective member 1140, and first to third side surfaces 1135, 1137, and 1139 that are exposed to the outside. Here, the bottom surface 1131, the inclined surface 1133, and a first side surface 1135 of the molding member 1130 may be formed in a rectangular shape, and second and third side surfaces 1137 and 1139 may be formed in a triangular shape, and more preferably, a right-angled triangular shape.

The bottom surface 1131 of the molding member 1130 may face the top surface of the substrate 1110. A shape and/or a size of a bottom surface 1131 of the molding member 1130 may correspond to a shape and/or a size of the top surface of the substrate 1110.

The inclined surface 1133 of the molding member 1130 may face the bottom surface (i.e., a reflective surface) 1141 of the reflective member 1140. Through such an arrangement, a diagonal boundary surface 1150 may be formed between the molding member 1130 and the reflective member 1140. A shape and/or a size of the inclined surface 1133 of the molding member 1130 may correspond to a shape and/or a size of the reflective surface 1141 of the reflective member 1140. Also, the inclined surface 1133 of the molding member 1130 may be formed to be a certain distance apart from the light-emitting device 1120.

The inclination of the diagonal boundary surface 1150 may be appropriately selected in consideration of light reflection efficiency and formability. For example, the inclination of the boundary surface 1150 may be an angle between 30 degrees and 60 degrees, but is not limited thereto.

The first to third side surfaces 1135, 1137, and 1139 of the molding member 1130 may be exposed to the outside. Therefore, light emitted from the upper portion of the light-emitting device 1120 may be reflected by the diagonal boundary surface 1150 and emitted to the outside through the first to third side surfaces 1135, 1137, and 1139 of the molding member 1130.

The reflective member 1140 may be disposed on the molding member 1130 and may be formed in a shape corresponding to a shape of the molding member 1130. For example, the reflective member 1140 may be formed in a shape corresponding to a shape of the molding member 1130 rotated by 180 degrees. The reflective member 1140 may also be formed by using an injection molding method or a transfer molding method.

The reflective member 1140 may form a body of the light-emitting device package 1100 together with the molding member 1130 and reflect light emitted from the light-emitting device 1120 to improve light emission efficiency of the light-emitting device 1120.

The reflective member 1140 may include an epoxy resin or a silicon resin having excellent reflection characteristics, but is not limited thereto. The reflective member 1140 may include an additive material like titanium dioxide (TiO₂) or silicon dioxide (SiO₂) in order to improve reflection characteristics.

The reflective member 1140 may be formed in a triangular prism-like shape corresponding to the shape of the molding member 1130. A cross-section of the reflective member 1140 may also be formed in a triangular shape, and more preferably, a right-angled triangular shape. The reflective member 1140 may be coupled to face the molding member 1130, thereby forming a cuboidal package body. Here, the molding member 1130 may be formed, such that the cross-sectional area thereof gradually decreases in a direction from a lower portion toward an upper portion, and the reflective member 1140 may be formed, such that the cross-sectional area thereof gradually increases in a direction from a lower portion toward an upper portion. Therefore, the package body may be formed to have a constant cross-sectional area regardless of its height.

The reflective member 1140 includes a bottom surface (i.e., a reflective surface) 1141 that meets the molding member 1130 and a top surface 1143, a first side surface 1145, a second side surface (not shown), and a third side surface (not shown) that are exposed to the outside. Here, the reflective surface 1141, the top surface 1143, and the first side surface 1145 of the reflective member 1140 may be formed in rectangular shapes, and second and third side surfaces may be formed in triangular shapes, and more preferably, right-angled triangular shapes.

The reflective surface 1141 of the reflective member 1140 may be disposed to face the inclined surface 1133 of the molding member 1130. A shape and/or a size of the reflective surface 1141 of the reflective member 1140 may correspond to a shape and/or a size of the inclined surface 1133 of the molding member 1130. Therefore, light emitted from an upper portion of the light-emitting device 1120 may be reflected by the reflective surface 1141 of the reflective member 1140 and emitted through three side surfaces of the light-emitting device package 1100.

The diagonal boundary surface 1150 may be formed between the reflective member 1140 and the molding member 1130. The inclination of the diagonal boundary surface 1150 may be appropriately selected in consideration of light reflection efficiency and formability.

The top surface 1143, the first side surface 1145, the second side surface, and the third side surface of the reflective member 1140 may be arranged to be exposed to the outside.

In the case of the side-view type light-emitting device package 1100 having the above-described structure, light emitted from the light-emitting device 1120 may be reflected by the top surface of the substrate 1110 and the reflective surface 1141 of the reflective member 1140 and may be emitted to the outside through the first to third side surfaces 1135, 1137, and 1139 of the molding member 1130. In other words, light emitted from the light-emitting device 1120 may be emitted to the outside through three side surfaces of the package body.

According to another embodiment, the side emitting light-emitting device package 1100 may further include reflection members arranged on the top surface and the bottom surface of the molding member 1130, respectively. In this case, light emitted from the light-emitting device 1120 may be reflected by the substrate 1110 and reflective members and may be emitted to the outside through the first side surface 1135 of the molding member 1130. In other words, light emitted from the light-emitting device 1120 may be emitted to the outside through one side surface of the package body.

As described above, the side-view type light-emitting device package 1100 according to the present disclosure may include a molding member, which has a preset shape and is disposed on a substrate and a light-emitting device, and a reflective member, which has a shape corresponding to that of the molding member and is disposed on the molding member, thereby emitting light emitted from the light-emitting device through three side surfaces of a package body.

Also, the side-view type light-emitting device package 1100 may include a substrate disposed in a direction parallel to the ground, light-emitting devices arranged on the substrate and emitting light in an upward direction, and a molding member and a reflection member having preset shapes and arranged on the substrate and the light-emitting devices, thereby reducing the thickness of the package body and effectively improving heat dissipation characteristics. Also, the side-view type light-emitting device package 1100 may effectively improve light extraction efficiency while having low thermal resistance.

For reference, Table 1 below is a table showing a light intensity changing rate of a side-view type light-emitting device package according to the related art and a light intensity changing rate of a side-view type light-emitting device package according to the present embodiment.

TABLE 1

| | Initial light | light intensity | light intensity |
|---|---|---|---|
| | intensity | after Aging | Changing Rate |
| Side-view type | 46.75 μmol | 40.04 μmol | 0.856471 |
| light-emitting | | | |
| device package | | | |
| according to the | | | |
| related art | | | |
| Side-view type | 35.74 μmol | 34 μmol | 0.951315 |
| light-emitting | | | |
| device package | | | |
| according to | | | |
| present | | | |
| embodiment | | | |

As shown in Table 1, a light intensity changing rate after aging with respect to an initial value of the side-view type light-emitting device package according to related art is 0.856471, and a light intensity changing rate after aging with respect to an initial value of the side-view type light-emitting device package according to the present embodiment is 0.951315. As described above, in the case of the side-view type light-emitting device package according to the present embodiment, there is no significant difference between the initial light intensity and the light intensity after aging.

FIG. 14 is a cross-sectional view of a light-emitting device according to an embodiment of the present disclosure.

Referring to FIG. 14, a light-emitting device 1300 according to an embodiment may include a growth substrate 1310, a light-emitting structure 1350 on the growth substrate 1310, and a first conductivity type metal layer 1360 and a second conductivity type metal layer 1370 on the light-emitting structure 1350.

The light-emitting structure 1350 may be formed by sequentially growing a first conductivity type semiconductor layer 1320, an active layer 1330, and a second conductivity type semiconductor layer 1340 on the growth substrate 1310.

The light-emitting structure 1350 may include a Group III-V compound semiconductor, e.g., AlInGaN, GaAs, GaAsP, or GaP-based compound semiconductor, and light may be generated as electrons and holes provided from the first conductivity type semiconductor layer 1320 and the second conductivity type semiconductor layer 1340 are recombined in the active layer 1330. The light-emitting structure 1350 may emit light having different wavelengths according to composition ratios of a compound semiconductor.

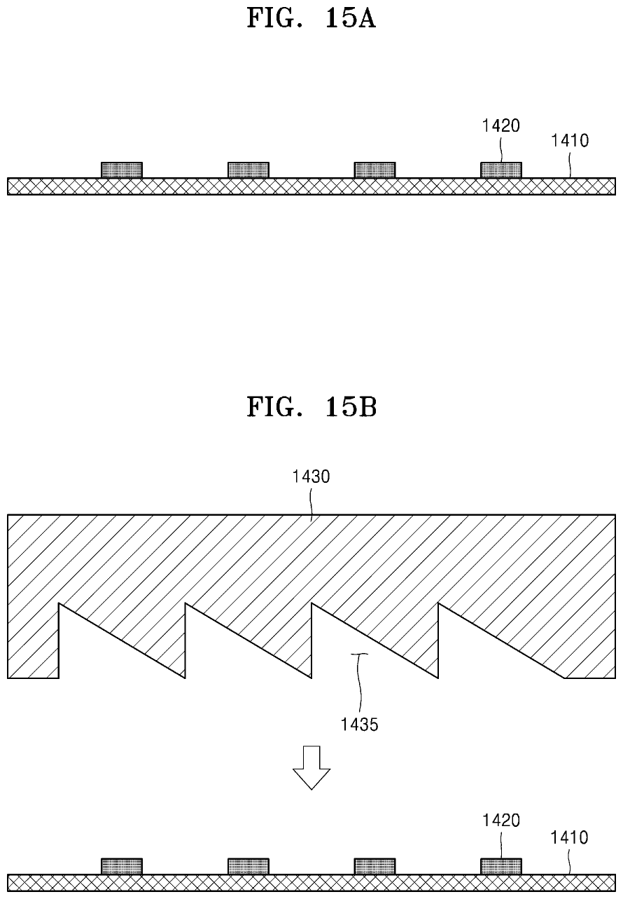

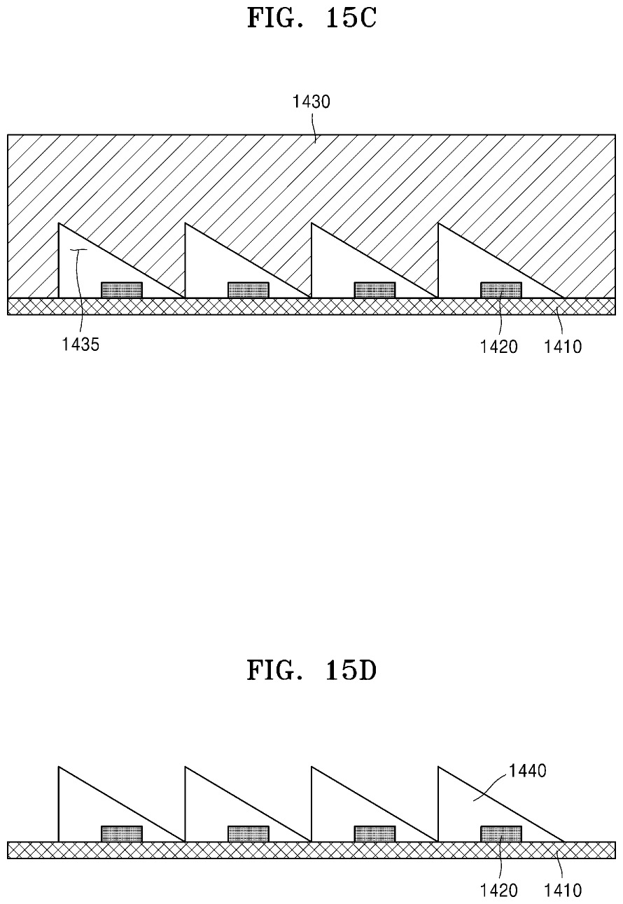

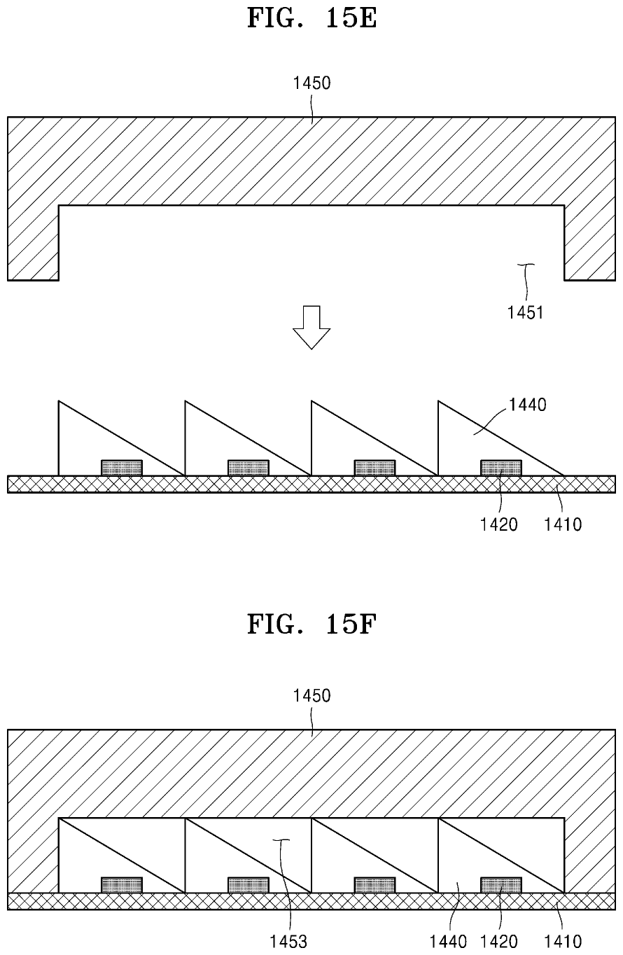

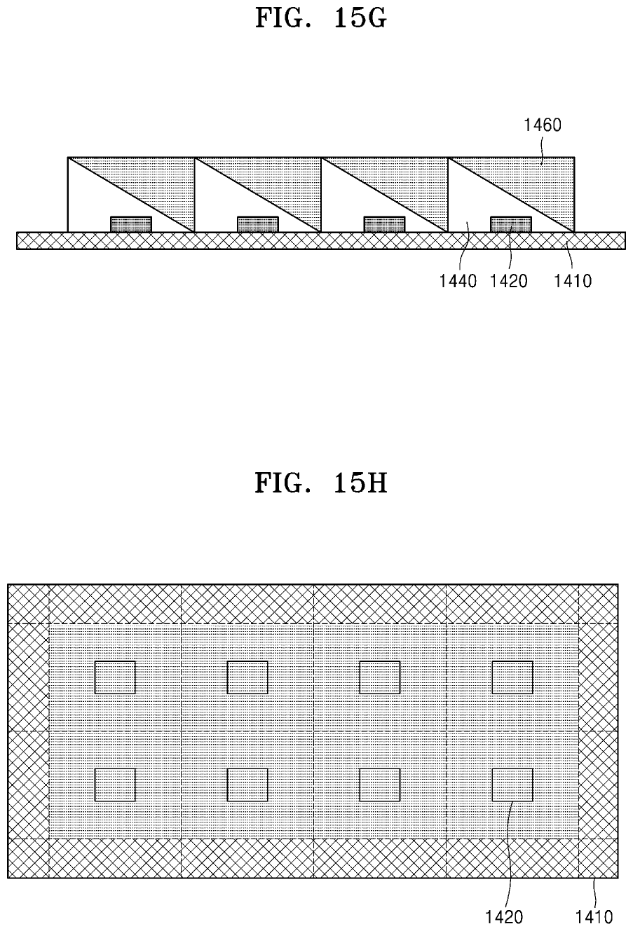

FIGS. 15A through 15H are diagrams for describing a method of manufacturing a side-view type light-emitting device package according to an embodiment of the present disclosure.

Referring to FIG. 15A, a substrate 1410 on which a preset circuit pattern is formed may be formed. The substrate 1410 may be a PCB substrate or a FPCB substrate.

A plurality of light-emitting devices 1420 may be mounted on the substrate 1410. Here, the plurality of light-emitting devices 1420 may be electrically connected to the substrate 1410 by being flip-chip bonded or wire-bonded to the substrate 1410.

The plurality of light-emitting devices 1420 may be arranged on the substrate 1410 in a matrix shape. The plurality of light-emitting devices 1420 may be arranged to maintain a constant interval therebetween.

Referring to FIGS. 15B to 15D, a first mold apparatus 1430 having a saw-toothed wheel-like shaped cross section may be prepared. The first mold apparatus 1430 may be moved to above the substrate 1410, such that the bottom surface of the first mold apparatus 1430 faces the top surface of the substrate 1410.

A plurality of first openings 1435 having a saw-toothed wheel-like shape may be formed in a lower portion of the first mold apparatus 1430. One light-emitting device 1420 may be disposed in each of the plurality of first openings 1435. In this state, an epoxy resin or a silicon resin may be injected into the plurality of first openings 1435 formed in the lower portion of the first mold apparatus 1430 by using a separate injection apparatus (not shown). When a predetermined time is elapsed under conditions including a predetermined temperature and a certain pressure, the epoxy resin or the silicon resin injected into the plurality of first openings 1435 is firmly cured, thereby forming a plurality of molding members 1440 on the substrate 1410 and the plurality of light-emitting devices 1420. Thereafter, the first mold apparatus 1430 may be separated from the substrate 1410.

Each of the molding members 1440 may be formed in a shape corresponding to a shape of a first opening 1435 formed in the lower portion of the first mold apparatus 1430. For example, each of the molding members 1440 may be formed in a triangular prism-like shape. A cross-section of the molding member 1440 may have a right-angled triangular shape.

Referring to FIGS. 15E to 15G, a second mold apparatus 1450 having a ‘U’-shaped cross section may be prepared. A second opening 1451 having a rectangular shape may be formed in a lower portion of the second mold apparatus 1450. Here, the height of the second opening 1451 may be the same as the height of the molding member 1440, and the width of the second opening 1451 may be the same as a sum of the widths of the molding members 1440.

The second mold apparatus 1450 may be moved to above the substrate 1410, such that the bottom surface of the second mold apparatus 1450 faces the top surface of the substrate 1410. A plurality of third openings 1453 may be formed between the bottom surface of the second mold apparatus 1450 and the top surfaces of the molding members 1440. The third openings 1453 may be formed in a triangular prism-like shape.

In this state, an epoxy resin or a silicon resin to which titanium dioxide (TiO₂) or silicon dioxide (SiO₂) is added may be injected into the plurality of third openings 1453 formed between the second mold apparatus 1450 and the molding members 1440 by using a separate injection apparatus (not shown). When a certain time is elapsed under conditions including a certain temperature and a certain pressure, the epoxy resin or the silicon resin injected into the plurality of third openings 1453 is firmly cured, thereby forming a plurality of reflective members 1460 on the plurality of molding members 1440. Thereafter, the second mold apparatus 1450 may be separated from the substrate 1410.

Each of the reflective members 1460 may have a shape corresponding to a shape of a third opening 1453 formed between the bottom surface of the second mold apparatus 1450 and the top surface of the molding member 1440. For example, each reflective member 1460 may be formed in a triangular prism-like shape. A cross-section of the reflective member 1460 may have a right-angled triangular shape.

The plurality of reflective members 1460 may be coupled to the plurality of molding members 1440 such that the reflective members 1460 face the molding members 1440, thereby forming a plurality of package bodies having a cubic shape or a cuboidal shape.

Referring to FIG. 15H, the plurality of package may be separated into unit package regions through a package separation process. The package separation process may include, for example, a breaking process of separating chips by applying a physical force using a blade, a laser scribing process of separating chips by irradiating a laser beam to the boundaries between chips, and an etching process of separating chips using wet etching or dry etching, but is not limited thereto.

Through the package separation process, a plurality of side-view type light-emitting device packages may be manufactured. The plurality of side-view type light-emitting device packages may each include a molding member, which is formed on a substrate and light-emitting devices and has a preset shape, and a reflective member, which has a shape corresponding to the shape of the molding member and is formed on the molding member, thereby effectively emitting light emitted by the light-emitting devices through three side surfaces of a package body.

Meanwhile, the example embodiments of the present disclosure have been described above, but various modifications may be made therein without departing from the scope of the present disclosure. Therefore, the scope of the present disclosure is not limited to the above-described embodiments and should be determined not only by the claims described below, but also by equivalents of the claims.

1. A surface light source slim module comprising:
a substrate extending from one side to another;
a plurality of packages mounted on top of the substrate in a direction from one side to another;
a first reflective layer formed on top of the substrate and having a plurality of holes;
a molding member, which is formed on top of the first reflective layer, covers the plurality of packages and the first reflective layer, and comprises a front portion through which light is output and a rear portion facing the front portion; and
a second reflective layer formed on top of the molding member, wherein
the first reflective layer and the second reflective layer reflect light output from the plurality of packages to be concentrated on the front portion of the molding member, and a direction in which light is output from the plurality of packages and a direction in which light is output to the front portion of the molding member are parallel to each other.

2. The surface light source slim module of claim 1, wherein the plurality of packages are side-view packages, and a direction in which light is output from the side-view packages and the direction in which light is output to the front portion of the molding member are the same.

3. The surface light source slim module of claim 1, wherein the plurality of packages are arranged in the plurality of holes of the first reflective layer, respectively.

4. The surface light source slim module of claim 1, wherein a depth of the holes of the first reflective layer is smaller than a thickness of the plurality of packages.

5. The surface light source slim module of claim 1, wherein at least one of the first reflective layer and the second reflective layer includes at least one of polyester (PET), aluminum, and silver.

6. The surface light source slim module of claim 1, wherein at least one of the first reflective layer and the second reflective layer is formed by being coated, by being formed in advance and attached, or by repeatedly stacking a plurality of reflective sheets.

7. The surface light source slim module of claim 1, wherein the molding member is formed by being molded with a resin to which a diffusing agent is added at a certain ratio to diffuse light.

8. The surface light source slim module of claim 1, further comprising a rear reflective member, which is positioned at a rear portion of the substrate to reflect light output to the rear portion of the molding member toward the front portion of the molding member.

9. A surface light source slim module comprising:
a substrate extending from one side to another;
a plurality of packages mounted on top of the substrate in a direction from one side to another;
a first reflective layer formed on top of the substrate and having a plurality of holes;
a molding member, which is formed on top of the first reflective layer, covers the plurality of packages and the first reflective layer, and comprises a front portion through which light is output and a rear portion facing the front portion;
a second reflective layer formed on top of the molding member; and
a third reflective layer stacked on top of the first reflective layer to reflect light output to the rear portion of the molding member toward the front portion of the molding member, wherein
the first reflective layer and the second reflective layer reflect light output from the plurality of packages to be concentrated on the front portion of the molding member, and a direction in which light is output from the plurality of packages and a direction in which light is output to the front portion of the molding member are perpendicular to each other.

10. The surface light source slim module of claim 9, wherein the plurality of packages are arranged in the plurality of holes of the first reflective layer, respectively.

11. The surface light source slim module of claim 9, wherein a depth of the holes of the first reflective layer is smaller than a thickness of the plurality of packages.

12. The surface light source slim module of claim 9, wherein at least one of the first reflective layer, the second reflective layer, and the third reflective layer is formed of at least one of polyester (PET), aluminum, and silver.

13. The surface light source slim module of claim 1, wherein at least one of the first reflective layer, the second reflective layer, and the third reflective layer is formed by being coated, by being formed in advance and attached, or by repeatedly stacking a plurality of reflective sheets.

14. The surface light source slim module of claim 9, wherein the molding member is formed by being molded with a resin to which a diffusing agent is added at a certain ratio.

15. The surface light source slim module of claim 9, wherein a thickness of the molding member gradually increases in a direction from a front portion of the substrate to a rear portion of the substrate, and the second reflective layer is formed to be inclined to correspond to a changing thickness of the molding member.

16. The surface light source slim module of claim 9, further comprising a rear reflective member positioned at the rear portion of the substrate to reflect light output to the rear portion of the molding member toward the front portion of the molding member, wherein the third reflective layer is stacked between the rear reflective member and the plurality of packages.

17. A method of manufacturing a surface light source slim module, the method including:
preparing a substrate extending from one side to another;
mounting a plurality of light-emitting device packages on top of the substrate to be apart from one another in a direction from one side to another;
forming a first reflective layer on top of the substrate on which the plurality of light-emitting device packages are mounted;
forming a molding member, which comprises a front portion through which light is output and a rear portion facing the front portion, on top of the first reflective layer; and
forming a second reflective layer on top of the molding member, wherein,
in the mounting of the light-emitting device packages, a direction in which light is output from the plurality of light-emitting device packages is identical and parallel to a direction in which light is output to the front portion of the molding member.

18. The method of claim 17, further comprising forming a rear reflective member at a rear portion of the surface light source slim module.

19. The method of claim 18, further comprising forming a third reflective layer on the first reflective layer between the plurality of packages and the rear reflective member.

20. The method of claim 17, wherein, in the forming of the molding member, the molding member is formed, such that a thickness of the molding member gradually increases in a direction from a front portion of the substrate to a rear portion of the substrate, and, in forming of the second reflective layer, the second reflective layer is formed to be inclined in correspondence to a changing thickness of the molding member.
